(19) United States
(12) Patent Application Publication
(10) Pub. No.: US 2026/0344139 A1
(43) Pub. Date: Oct. 29, 2026

(54) METHOD FOR PREPARING A STACK IN VIEW OF A BONDING

(71) Applicant: COMMISSARIAT A L'ENERGIE ATOMIQUE ET AUX ENERGIES ALTERNATIVES, Paris (FR)

(72) Inventors: Virginie MAFFINI ALVARO, Grenoble cedex 09 (FR); Bernard AVENTURIER, Grenoble cedex 09 (FR); Jeannet BERNARD, Grenoble cedex 09 (FR); Florian FEDELI, Grenoble cedex 09 (FR); Eléonore PRINCE, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/139,089

(22) PCT Filed: Dec. 13, 2023
(86) PCT No.: PCT/EP2023/085648

§ 371 Date: Jun. 13, 2025

(30) Foreign Application Priority Data
Dec. 16, 2022 (FR) FR2213584

(51) Int. Cl. H10H 29/01; H10H 29/24

(52) U.S. Cl. CPC H10H 29/011; H10H 29/24

(57) ABSTRACT

A method for preparing a stack includes providing a stack having a substrate surmounted by a plurality of structures. Each structure includes a pad having a top and at least one flank, a first layer surmounting the substrate, the first layer covering a part of the flank of the pad, a second layer covering at least the top of the pad. The structure includes a removal portion covering an upper part of the flank of the pad and formed by at least one from among the first layer and the second layer, and a covering portion, covering a lower part of the flank and extending from the removal portion. The removal portion is then removed, while leaving the covering portion in place to form a protrusion.

### TECHNICAL FIELD OF THE INVENTION

The present invention relates to the preparation of a substrate, in particular, in view of its bonding with another substrate. It relates, in particular, to the manufacturing of optoelectronic and microelectronic devices, It applies, for example, particularly advantageously, to the field of assembling a substrate having copper-based elements with a substrate covered with a copper film.

### PRIOR ART

The assembly of two substrate is a very common operation in microelectronics and optoelectronics. Such an assembly can, in particular, have the aim of transferring elements, for example, photoelements such as pixels, from one substate to another.

A common technique for assembling two substrates illustrated in FIGS. 1A to 1C is based on a direct bonding between protrusions 200′ with the basis of a dielectric, for example, SiO₂, located on the surface of a first of the two substrates, and the second substrate 2′. Other elements of the first substrate 1′, typically copper pillars 100′, are removed with respect to the SiO₂ protrusions 200′. During the step of assembling two substrates, a heating step causes a dilatation of the copper pillars. The dilatation of the SiO₂ protrusions occurring parallel is less significant than that of the copper pillars. Due to this, by means of a correct sizing of the removal of the pillars with respect to the SiO₂ protrusions, the pillars are located at the end of the level heating step with the SiO₂ protrusions, and in contact with the surface of the second substrate.

If this method is operational in certain contexts, it is however not applicable to all the substrates, and in particular, when the latter comprise metals, the melting point of which is less than the temperature at which the material of the removed elements can have a volume expansion. As an example, the annealing temperature of copper is 350 °C, while certain materials used to be able to require such assemblies have melting points of around 250 °C It is therefore impossible to implement this solution when these materials are involved.

The heating step can moreover cause high distortion and high mechanical stress problems within the substrates, when the latter contain materials having thermal dilatation coefficients which are too different from one another. This is, in particular, the case, when the second substrate comprises a glass-based support, covered with a thin copper layer.

Another disadvantage of this method resides in the accuracy required in the sizing of the removal of the copper pillars, with respect to the SiO₂ protrusions. Indeed, a variation in the value of this removal, for example, due to manufacturing hazards, could cause, at the time of dilatation of the copper pillars, unintentional disbonding within the substrates.

Documents US 2022/173161 A1, US 2022/352442 A1 and US 2017/069804 A1 disclose methods for bonding a first substrate on a second substrate through protrusions formed on the first substrate. These methods are not optimal, however.

An aim of the present invention is therefore to propose a method for preparing a substrate in view of an assembly with another substrate, this method not requiring subjecting the substrate to high temperatures.

### SUMMARY OF THE INVENTION

To achieve this aim, according to an embodiment, a method for preparing a stack is provided, comprising the following steps:
providing a stack comprising a substrate surmounted by a plurality of structures separated by trenches, each structure comprising:
   a pad comprising a top and at least one flank,
   a first layer with the basis of a first material and surmounting the substrate, the first layer covering at least one part of the flank of the pad,
   a second layer with the basis of a second material and covering at least the top of the pad,
   a removal portion, covering, preferably by being in direct contact with, an upper part of the flank of the pad, the upper part of the flank extending from the top of the pad, the removal portion being formed by at least one from among the first layer and the second layer,
   a covering portion, covering, preferably by being in direct contact with, a lower part of the flank of the pad and extending from the removal portion, the covering portion being formed by the first layer,
removing the second layer,
removing the removal portion while leaving the covering portion in place, so as to expose the upper part of the flank of the pad, the upper part of the flank of the pad forming a protrusion beyond the covering portion.

The protrusion thus formed is conducive to a bonding on another surface, for example, the upper face of a transfer support.

A second aspect of the invention relates to a stack comprising a substrate surmounted by a plurality of structures separated by trenches, each structure comprising:
a pad comprising a top and at least one flank,
a first layer with the basis of a first material and surmounting the substrate, the first layer covering at least one part of the flank of the pad,
a covering portion formed by the first layer, covering, preferably by being in direct contact with, a lower part of the flank of the pad and exposing an upper part of the flank of the pad, the upper part of the pad forming a protrusion with respect to the first layer.

A third aspect of the invention relates to a method for bonding or transferring at least one pad comprised in a stack according to the second aspect of the invention on a receiving stack:
Providing a stack according to the second aspect of the invention,
Providing a receiving stack having an upper face,
Performing a direct bonding of the top of the at least one pad of the stack on the upper face of the receiving stack.

The protrusions formed during the preparation method indeed enable, during the bonding method, an effective bonding. Quite specifically, it is not necessary to proceed with a heating step risking causing high distortions and/or high mechanical stresses within the stacks, as was the case in the prior art. It is optionally possible to proceed with a consolidation annealing after the direct bonding to improve the adhesion between the topes of the pads and the upper face of the receiving stack, but such an annealing is performed at temperatures less than the temperatures for which mechanical deformations can occur.

Moreover, this bonding method does not require a dimensional control greater than the control commonly accessible in the industry.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 1C represent a method for assembling two substrates according to the prior art. FIG. 1A illustrates a stack according to the prior art comprising a substrate surmounted by pillars removed with respect to protrusions with the basis of a dielectric. The protrusions laterally cover the pillars.

FIG. 1B illustrates the reversal of the stack according to the prior art, and its placing side by side of a receiving stack.

FIG. 1C illustrates the assembly of the two stacks and their bonding by heating. FIG. 1C illustrates, in particular, the dilatation of the pillars.

FIGS. 2A to 2J illustrate a first embodiment of the method according to the invention. FIG. 2A represents the provision of a primary stack comprising a substrate and a first primary layer surmounting the substrate.

FIG. 2B illustrates the formation of a first etching mask on the first primary layer.

FIG. 2C represents the formation of cavities in the first primary layer.

FIG. 2D illustrates the formation of a third primary layer in the cavities and on the first primary layer.

FIG. 2E represents the tapering of the third primary layer, so as to form pads extending into the cavities.

FIG. 2F represents the formation of a second primary layer on the pads and the first primary layer.

FIG. 2G represents the formation of a second etching mask on the second primary layer. FIG. 2H illustrates the formation through the second etching mask of trenches extending into the second primary layer and the first primary layer. A plurality of second layers is thus formed from the second primary layer and a plurality of first layers from the first primary layer.

FIG. 2I illustrates the removal of the second etching mask.

FIG. 2J illustrates the removal of the second layers and a part of the first layers extending, before the removal, from the second layers.

FIGS. 3A to 3J illustrate a second embodiment of the method according to the invention.

FIG. 3A represents the provision of a stack comprising a substrate, a first primary layer surmounting the substrate and a first primary sublayer surmounting the first primary layer.

FIG. 3B represents the formation of a first etching mask on the first primary sublayer.

FIG. 3C represents the formation of secondary cavities in the first primary layer and in the first primary sublayer through the first etching mask.

FIG. 3D represents the formation of a third primary layer in the secondary cavities and on the first primary sublayer.

FIG. 3E illustrates the tapering of the third primary layer, so as to form pads extending into the secondary cavities and level with the first primary sublayer.

FIG. 3F illustrates the formation of a second primary sublayer on the pads and on the first primary sublayer. The first primary sublayer and the second primary sublayer form a second primary layer.

FIG. 3G represents the formation of a second etching mask on the second primary layer.

FIG. 3H illustrates the formation through the second etching mask of trenches extending into the second primary layer and the first primary layer. A plurality of second layers is thus formed from the second primary layer and a plurality of first layers from the first primary layer.

FIG. 3I illustrates the removal of the second etching mask.

FIG. 3J illustrates the removal of the second layers, thus forming a protrusion.

FIGS. 4A to 4H illustrate a third embodiment of the method according to the invention.

FIG. 4A represents the provision of a stack comprising a substrate and a first primary layer surmounting the substrate. The first primary layer comprises cavities.

FIG. 4B illustrates the formation of a third primary layer in the cavities and on the first primary layer.

FIG. 4C illustrates the tapering of the third primary layer, so as to single out the latter into individual pads, projecting with respect to the first primary layer.

FIG. 4D represents the formation of a second primary layer on the pads and on the first primary layer.

FIG. 4E represents the formation of a second etching mask on the second primary layer.

FIG. 4F illustrates the formation through the second etching mask of trenches extending into the second primary layer and the first primary layer. A plurality of second layers is thus formed from the second primary layer and a plurality of first layers from the first primary layer.

FIG. 4G illustrates the removal of the second etching mask.

FIG. 4H illustrates the removal of the second layers, thus forming a protrusion.

FIGS. 5A and 5B are top views of the steps represented in FIGS. 2I, 3I and 4G. FIG. 5A illustrates an embodiment in which the pads are cylindrical with a square base.

FIG. 5B illustrates the case of circular cylindrical pads.

The drawings are given as examples and are not limiting of the invention. They constitute principle schematic representations intended to facilitate the understanding of the invention and are not necessarily to the scale of practical applications. In particular, the dimensions are not representative of reality.

### DETAILED DESCRIPTION OF THE INVENTION

Before starting a detailed review of the embodiments of the invention, optional features are stated below, which can optionally be used in association or alternatively:

According to an example, the substrate has a lower face, extending mainly along a transverse plane defined by a first direction and a second direction, the protrusion having a height Eₚᵣₒₜ along a third direction perpendicular to said transverse plane, such that Eₚᵣₒₜ≤0.5*E_{flank}, preferably Eₚᵣₒₜ≤0.3*E_{flank} and preferably Eₚᵣₒₜ≤0.1*E_{flank}, E_{flank} being the height of the flank taken along the direction Z. Eₚᵣₒₜ is thus measured, along Z, between an end of the covering portion and the top of the pad.

According to an example, Eₚᵣₒₜ≥5 nm, preferably Eₚᵣₒₜ≥10 nm. Preferably, Eₚᵣₒₜ≤50 nm, Eₚᵣₒₜ≤30 nm.

According to an example, the removal of the second layer and the removal of the removal portion are performed during one single etching step.

According to an embodiment, the removal portion is formed only by the first layer.

According to an example, prior to the removal step, the first layer extends up to the top of the pad. In particular, the second layer cannot cover the flank.

According to an example, the removal of the removal portion is performed by time control, as well as, preferably, by the etching selectivity of the different materials According to an embodiment, the removal portion is formed in part at least by the second layer. Thus, the second layer covers a part of the flank.

According to an example, the removal portion is formed only by the second layer. This makes it possible to very accurately control the height of the protrusion obtained with the removal of the removal layer. This makes it possible to resort only to very common steps and fully controlled in the industry. This also makes it possible to limit the number of steps to implement to remove the removal portion. This is thus conveyed by a time saving and an economic saving.

According to an example, the removal of the removal portion comprises the etching of the second layer selectively with regards to the first layer. The removal of the removal portion is performed, for example, by etching of the second layer stopping on the first layer.

According to a particular embodiment of the invention, the provision of the stack comprises the following steps:
Forming the First Layer,
Forming the pad,
Forming the second layer,
   and the formation of the second layer comprises the following substeps:
After the formation of the first layer and prior to the formation of the pad, forming a first sublayer of the second layer, the first sublayer surmounting the first layer,
After the formation of the pad, forming a second sublayer of the second layer, the second sublayer surmounting at least the pad.

According to a particular embodiment of the invention, the provision of the stack comprises the following steps:
Forming the first layer,
Forming the pad,
Forming the second layer,
   and the second layer is deposited on the pad and the first layer after the formation of the pad.

According to an example, the pads are formed of a third material, the third material being with the basis of one from among copper, aluminium, tungsten and titanium. Generally, the third material is an electrically conductive material, preferably a metal material.

According to an example, the first material is with the basis of one from among: SiO2, SiN and Si.

According to an example, the second material is with the basis of one from among SiN, SiO₂ and Si. The first and the second material can each be with the basis of a dielectric material.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers at least partially the second layer by being, either directly in contact with it, or by being separated from it by at least one other layer or at least one other element.

A layer can, moreover, be composed of several sublayers of one same material or of different materials.

By a substrate, a layer, a device, “with the basis” of a material M, this means a substrate, a layer, a device comprising this material M only or this material M and optionally other materials, for example, alloy elements, impurities or doping elements. Thus, a material with the basis of a III-N material can comprise a III-N material added with dopants. Likewise, a GaN-based layer typically comprises GaN and AIGaN or InGaN alloys.

The term “III-V material” makes reference to a semiconductor composed of one or more elements of column III and column V of Mendeleev's periodic table. Among the elements of column III, there are boron, gallium, aluminium, or also indium. Column V contains, for example, nitrogen, arsenic, antimony and phosphorus.

By “selective etching with regards to” or “etching having a selectivity with regards to”, this means an etching configured to remove a material A or a layer A with regards to a material B or a layer B, and having an etching speed of the material A greater than the etching speed of the material B. The selectivity is the ratio between the etching speed of the material A over the etching speed of the material B. The selectivity between A and B is referenced SA: B.

The roughness of a surface is a parameter characterising the state of this surface. It is most often associated in tribology with the characteristic depth of the ridges crossing the surface. The roughness of a surface is referenced Ra and is expressed typically in μm (1 μm=10⁻⁶ m) or nm (1 nm=10⁻⁹ m).

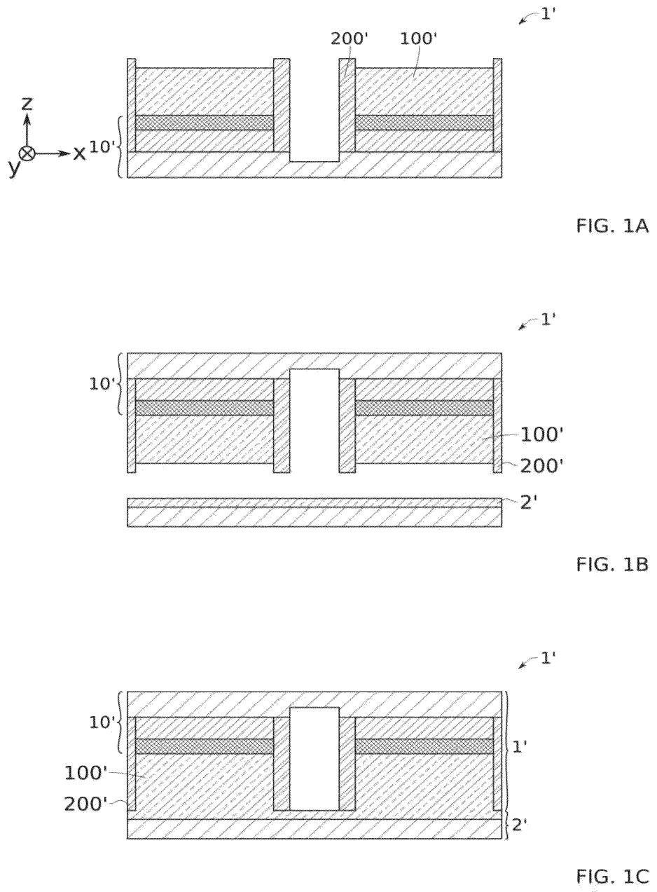

A preferably orthonormal system, comprising the axes X, Y, Z is represented in FIGS. 1A, 2A, 3A, 4A, 5A and 5B. This system is applicable by extension to the other figures.

In the present patent application, preferably thickness will be referred to for a layer and height will be referred to for a structure or a device. The height is taken perpendicularly to the transverse plane XY. The thickness is taken along a direction normal to the main extension plane of the layer. Thus, a layer typically has a thickness along Z, when it extends mainly along the transverse plane XY, and a projecting element, for example, an insulation trench, has a height along Z. The relative terms “on”, “under”, “underlying” preferably refer to positions taken along the direction Z.

The terms “substantially”, “around”, “about” mean “plus or minus 10%, preferably plus or minus 5%”.

A first step of the method according to the invention consists of the provision of a stack 1 comprising a substrate 10 and a plurality of structures 1000 surmounting the substrate 10 and separated by the trenches 400.

The substrate 10 has a lower face 12 extending mainly into a transverse plane XY defined by a first direction X and a second direction Y. The substrate 10 can also comprise an emitting layer 15 comprising a plurality of photoemitting elements. The photoemitting elements can, for example, be active nanowires or active microwires forming LEDs or micro-LEDs. These can, for example, be standard, two-dimensional LEDs (2D LEDs). Photoemitting elements typically have an elongate shape along a third direction Z perpendicular to the transverse plane XY. The emitting layer 15 is typically with the basis of one or more semiconductive materials.

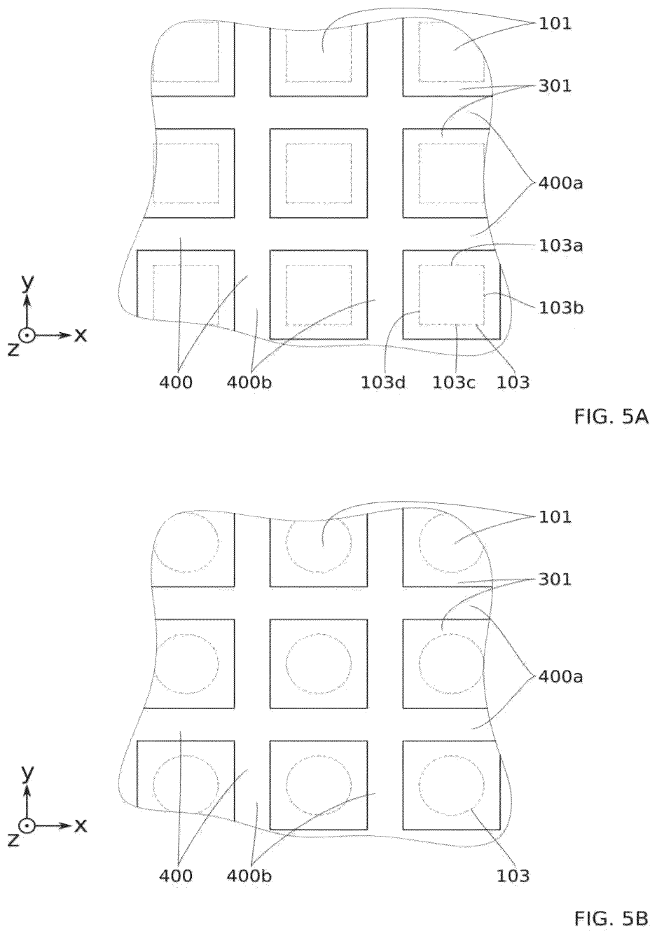

The structures 1000 have a cylindrical shape, preferably that of a straight cylinder, the generating straight lines of which extend along the third direction Z. The structures 1000 typically have a rectangular cross-section, preferably square cross-section, in a plane parallel to the transverse plane XY, as represented in FIGS. 5A and 5B.

The structures 1000 are separated from one another by trenches 400. These trenches are typically rectilinear. The trenches 400 can, for example, comprise a first series of trenches 400a and a second series of trenches 400b, the trenches 400b of the second series being perpendicular to the trenches 400a of the first series. The trenches 400a of the first series extend, for example, along the first direction X and those of the second series along the second direction Y, as represented in FIGS. 5A and 5B.

Each of the structures 1000 surmounting the substrate 10 comprises a pad 100 having a top 101 and at least one flank 103 having a height E_{flank} along the third direction Z. E_{flank} is advantageously greater than 500nm, typically substantially equal to 1 μm.

The top 101 of the pad 100 extends advantageously into a so-called upper plane 501, preferably parallel to the transverse plane XY.

The pad 100 typically has the shape of a cylinder, preferably a straight cylinder, the generating straight lines of which defining one or more side faces of the pad 100 preferably extend along the third direction Z. The pad 100 can, for example, have a polygonal shape in the transverse plane XY. The pad 100 thus has several side faces. In the particular case of a pad 100 having a rectangular, even square shape in the transverse plane XY, the pad 100 has four side faces 103a, 103b, 103c, 103d, as represented in FIG. 5A. The pad 100 can also have a circular cylindrical shape, as illustrated in FIG. 5B. Thus, it only has one single side face. In the case of a cylindrical pad, the at least one flank 103 of the pad 100 corresponds to one or the side face of the pad 100.

The pad 100 is preferably with the basis of a metal material, for example, copper, aluminium, tungsten, or also titanium.

Each pad 100 advantageously covers at least one photoemitting element comprised in the emitting layer 15. The photoemitting elements are thus located to the right of the pads 100 projecting along the transverse plane XY. They can be in direct contact with the pads 100, optionally through a layer called contact layer 16, being able, for example, to be aluminium-, titanium- or titanium nitride-based.

Each of the structures comprises, in addition, a first layer 200 having an upper face 201 preferably extending into a plane parallel to the transverse plane XY. According to an example, the first layer 200 directly surmounts the substrate 10, i.e. that its lower face 202 is in contact with the substrate 10. It has a thickness E₂₀₀ along the third direction Z. The first layer 200 covers at least one part of the flank 103 of the pad 100. It is thus in contact with the pad 100 over a non-zero height E_{covering} less than or equal to the height of the flank E_{flank}. Each of the structures 1000 further comprises a second layer 300 covering at least the top 101 of the pad 100. It can also cover at least one part of the first layer 200. The second layer 300 is preferably in direct contact with the top 101 of the pad 100, and optionally, the first layer 200. It has an upper face 301 preferably extending into a plane parallel to the transverse plane XY.

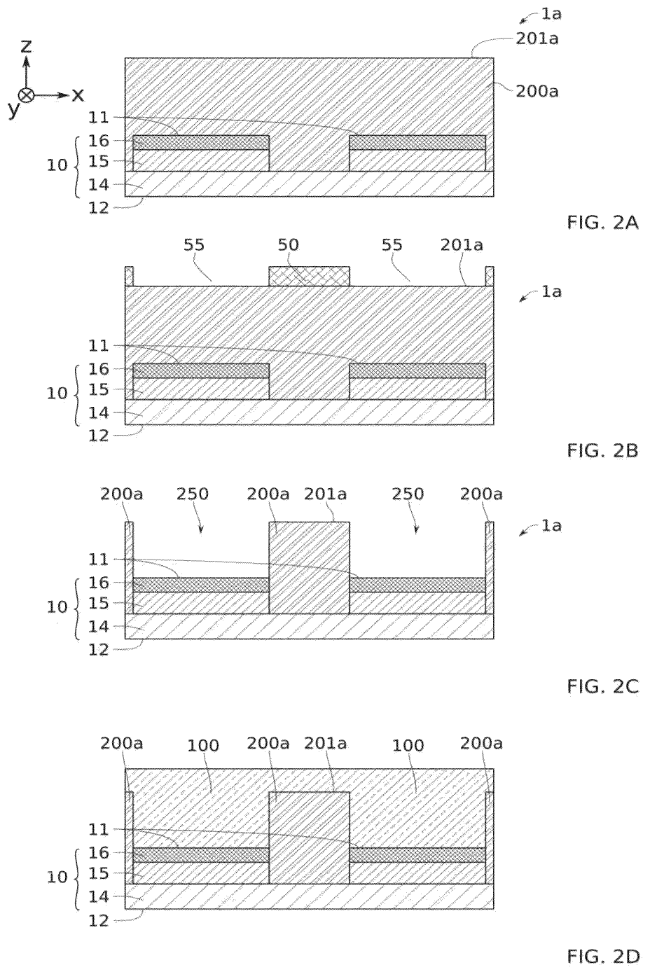

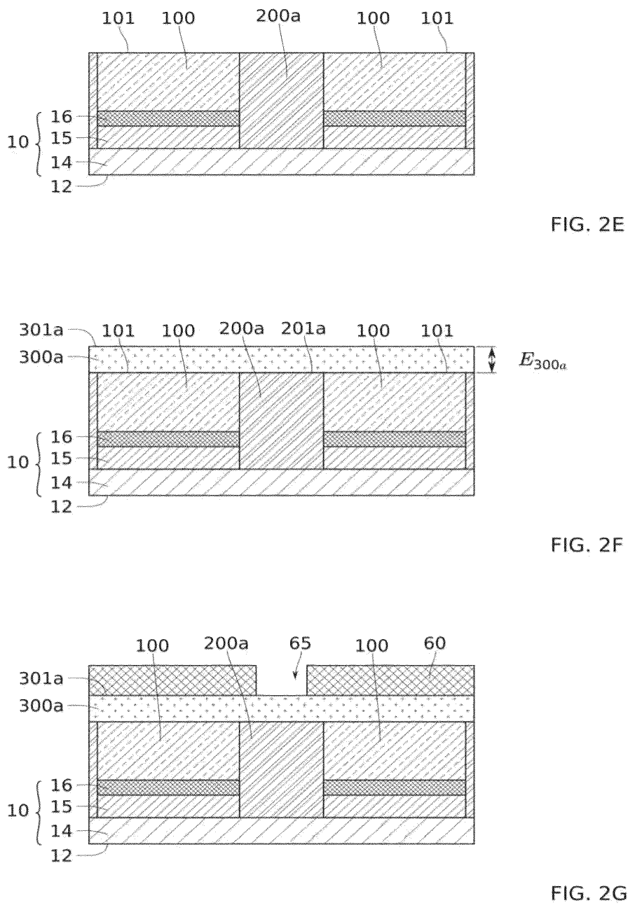

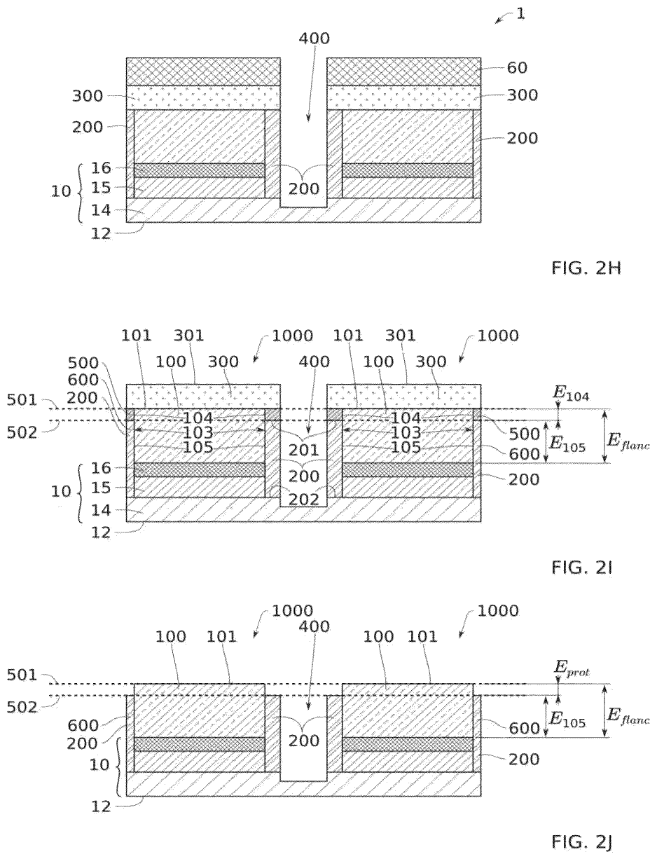

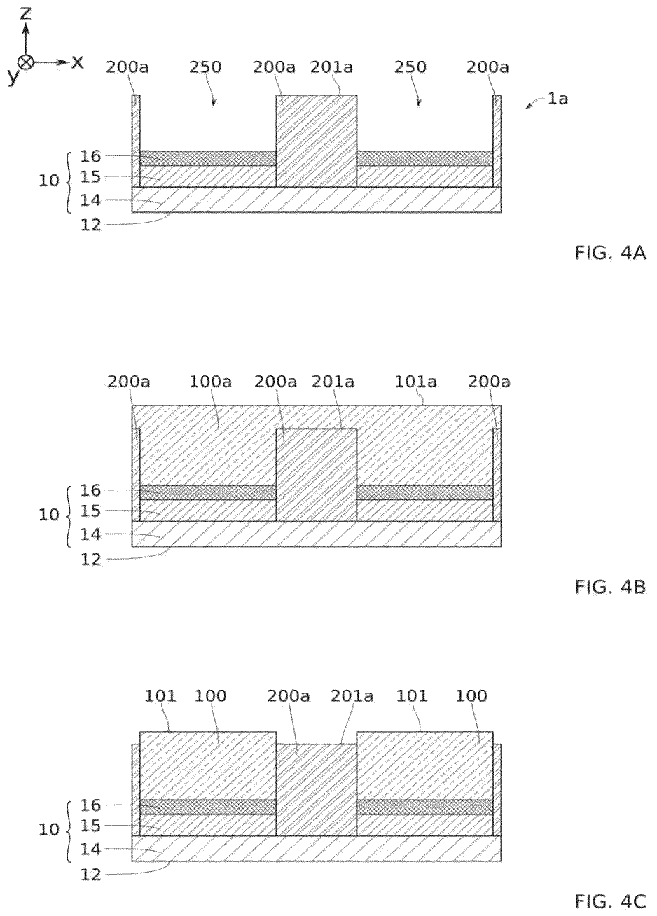

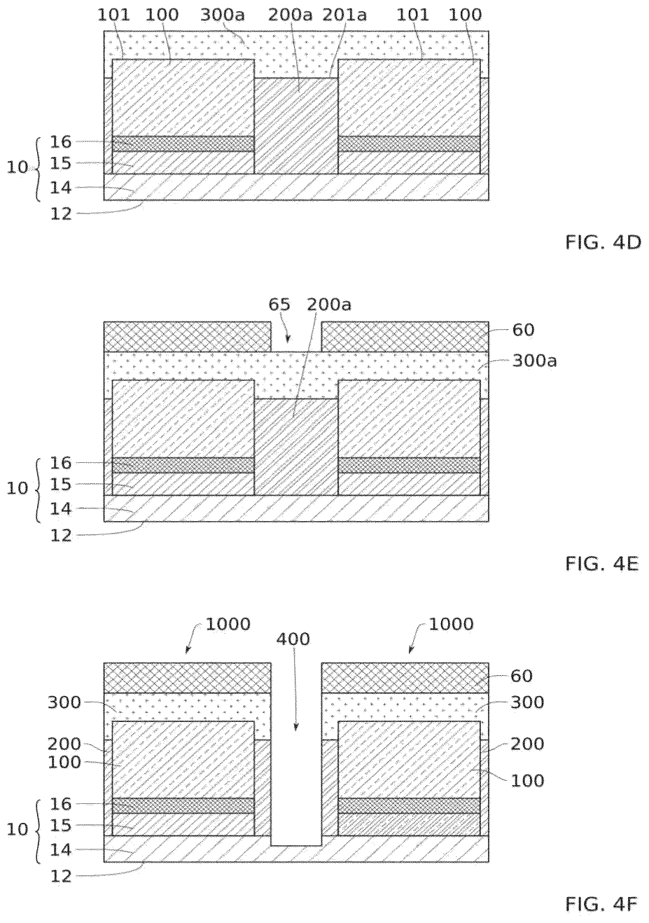

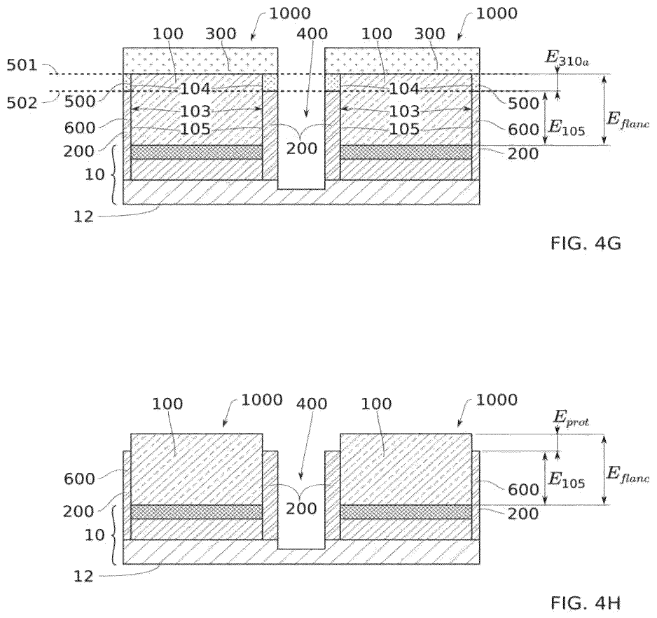

The stack 1 provided during the method according to the invention can, for example, be obtained according to the steps below:
Providing a primary stack 1a comprising, as illustrated in FIG. 2A:
   The substrate 10,
   A first primary layer 200a with the basis of the first material and covering the substrate 10.
Forming, in the first primary layer 200a, cavities 250 entirely passing through the first primary layer 200a along the third direction Z. This step is illustrated by FIGS. 2B and 2C.
Filling the cavities 250 with the third material, thus forming the pads 100 (FIGS. 2E, 4C).
Forming a second primary layer 300a with the basis of the second material and surmounting the pads 100 and the first layers 200 (FIGS. 2F, 3A, 3F, 4D).
Forming the trenches 400 entirely passing through the second primary layer 300a and the first primary layer 200a along the third direction Z. The formation of the trenches 400 makes it possible to single out and form the structures 1000, as illustrated in FIGS. 2H, 3J, 4F. They separate, in particular, the first layers 200 formed in the first primary layer 200a, and the second layers 300 formed in the second primary layer 300a, which will each form part of a structure 1000.

It is understood, however, that the stack 1 can be obtained according to any other embodiment.

Following the provision of the stack 1, a step of removing a removal portion 500 is implemented at each structure 1000.

The removal portion 500 is formed by at least one from among the first layer 200 and the second layer 300. It covers an upper part 104 of the flank 103 of the pad 100. In other words, it is adjacent, in a plane parallel to the plane XY, to the flank 103 of the pad 100, and this, in any point of the upper part 104 of the flank 103. The removal portion 500 is preferably in direct contact with the upper part 104 of the flank 103 of the pad 100. In the particular case of a pad 100 having several flanks, the upper part 104 advantageously extending into each of the flanks 103 of the pad 100.

The upper part 104 of the flank 103 extends from the top 101 of the pad 100. More specifically, the upper part 104 extends from the edge(s) of the pad 100 delimiting its top 101 and its flank 103. It has, along the third direction Z, a height E₁₀₄. The removal portion 500 extends along the third direction Z over a distance less than the height of the flank 103. Thus, E₁₀₄<E_{flank}.

The removal portion 500 can thus extend, along the third direction Z, between the upper plane 501 into which the top 101 of the pads 100 extends, and a lower plane 502 extending, along the third direction Z, between the transverse plane XY and the upper plane 501. During the step of removing the removal portion 500, a covering portion 600 is left in place. The covering portion 600 is formed by the first layer 200. It covers a lower part 105 of the flank 103 of the pad 100. In other words, it is adjacent, in a plane parallel to the plane XY, to the flank 103 of the pad 100, and this, in any point of the lower part 105 of the flank 103. The covering portion 600 is preferably in direct contact with the lower part 105 of the flank 103 of the pad 100.

The covering portion 600 extends from the removal portion 500, i.e. that the upper part 104 and the lower part 105 of the flank 103 of the pad 100 are in contact.

The lower part 105 of the flank 103 has, along the third direction Z, a height E₁₀₅. According to an example, the removal portion 500 and the covering portion 600 cover the entire flank 103 of the pad 100 over the entire height. Thus, E₁₀₄+E₁₀₅=E_{flank}.

The lower part 105 of the flank 103 is, during the removal of the removal portion 500, left covered by the covering portion 600.

Once the removal portion 500 is removed, the upper part 104 of the flank 103 forms a protrusion beyond the covering portion 600. The pad 100 thus projects along the third direction Z with respect to at least one remaining part of the first layer 200 corresponding to the covering portion 600.

The protrusion formed has a height Eₚᵣₒₜ along the third direction. Advantageously, Eₚᵣₒₜ is greater than or equal to 5 nm.

Different embodiments of the method according to the invention will now be described in more detail.

First example of an implementation of the method according to the invention

A first embodiment of the method according to the invention will now be described in reference to FIGS. 2A to 2J.

A first step consists of the provision of a primary element 1a comprising the substrate 10 and a first primary layer 200a surmounting the substrate 10 (FIG. 2A). A first etching mask 50 is then deposited on the upper face 201a of the first primary layer 200a (FIG. 2B) and a removal of certain parts of the first primary layer 200a is performed through openings 55 in the first etching mask 50, then, preferably, the latter is removed (FIG. 2C). This removal makes it possible to form cavities 250 in the first primary layer 200a. Preferably, the removal in the first primary layer 200a is done over its entire thickness along the third direction Z. In other words, preferably, the cavities 250 extend up to the upper face 11 of the substrate 10. Thus, an assembly is obtained, comprising the substrate 10 surmounted by the first primary layer 200a comprising the cavities.

The cavities 250 are then filled with the third material. It is, for example, possible to deposit a third primary layer 100a of third material extending into the cavities 250, in vertical alignment with the cavities 250 along the third direction Z and above the first primary layer 200a (FIG. 2D). A part of the third primary layer 100a can then be removed, for example, by chemical-mechanical polishing (CMP), so as to return it again along the third direction Z with the first primary layer 200a (FIG. 2E). The remaining portions of the third primary layer 100a, separated by the first primary layer 200a, constitute the pads 100. This way of proceeding, by deposition then polishing, makes it possible to reduce, even avoid any possible projection or removal of the pads 100 with respect to the first primary layer 200a.

As illustrated in FIG. 2F, a second primary layer 300a is then deposited on the upper face 201a of the first primary layer 200a and the top 101 of the pads 100. The second primary layer 300a has, along the third direction Z, a thickness E₃₀₀ₐ. Advantageously, E₃₀₀ₐ is less than or equal to 200 nm and/or greater than or equal to 20 nm, preferably substantially equal to 60 nm.

A second etching mask 60 is then formed on the second primary layer 300a (FIG. 2G).

The second etching mask 60 has openings 65 located in vertical alignment with the first primary layer 200a.

Following the deposition of the second etching mask 60, trenches 400 are formed through openings 65 in the second primary layer 300a, the first primary layer 200a, and optionally a portion of the substrate 10 (FIG. 2H). Preferably, the second etching mask 60 is then removed. The trenches 400 separate the structures 1000 described above. Preferably, the trenches pass through the entire thickness along the third direction Z of the second primary layer 300a and of the first primary layer 200a. Advantageously, at least some of the trenches 400 extend into the substrate 10. This can make it possible, according to the targeted applications, to single out different zones of the substrate 10, for example, to electrically insulate them from one another.

The formation of the trenches 400 makes it possible to divide the first primary layer 200a into a plurality of first layers 200 and the second primary layer 300a into a plurality of second layers 300. Thus, the stack 1 is obtained, comprising the substrate 10 surmounted by the structures 1000, each structure 1000 comprising a pad, a first layer 200 and a second layer 300.

In this embodiment, in each structure 1000, the first layer 200 and the pad 100 are substantially along the third direction Z. The second layer 300 does not cover the flank 103 of the pad 100. Thus, as illustrated in FIG. 2I, the removal portion 500 is only formed by a part of the first layer 200. The upper part 104 of the flank 103 of the pad 100 is only covered by the first layer 200. The lower part 105 of the flank 103, itself, is advantageously covered only by the first layer 200.

Advantageously, in this embodiment, during the removal of the removal portion 500, a part of the second layer 300 is also removed. It is understood that the removal of the second layer 300 is understood as the removal of the second layers 300 of each structure 1000. This comment extends to the mention of all the other elements common to all the structures 1000.

The removal of the removal portion 500 is done, for example, during the same step as the removal of the second layer 300. It is, for example, possible to implement an etching of the first material and of the second material, selective as regards the third material forming the pads 100. This etching also preferably has a selectivity between the first material and the second material. If V₁ is noted, the etching speed of the first material, if V₂ is noted, the etching speed of the second material, and if V₃ is noted, the etching speed of the third material, thus, preferably: V₂>V₁ and V₂>V₃. Preferably, V₂>10*V₁ and/or V₂>100*V₃. The selectivity between the first, second and third material has the direct consequence of the height Eₚᵣₒₜ of the protrusion formed during the removal of the removal portion 500. Thus, the height Eₚᵣₒₜ can be controlled by choosing these materials.

This embodiment is characterised by its implementation simplicity, in particular as relatively few steps are necessary for the formation of protrusions.

All the steps described in the scope of this first embodiment can be implemented in other embodiments of the method according to the invention. The advantages that these steps have, are also transposable to other embodiments. It is, in particular, possible to use a selective etching between the first, the second and the third material such as described above for the formation of the protrusion during other variants of the method according to the invention.

Second example of an implementation of the method according to the invention

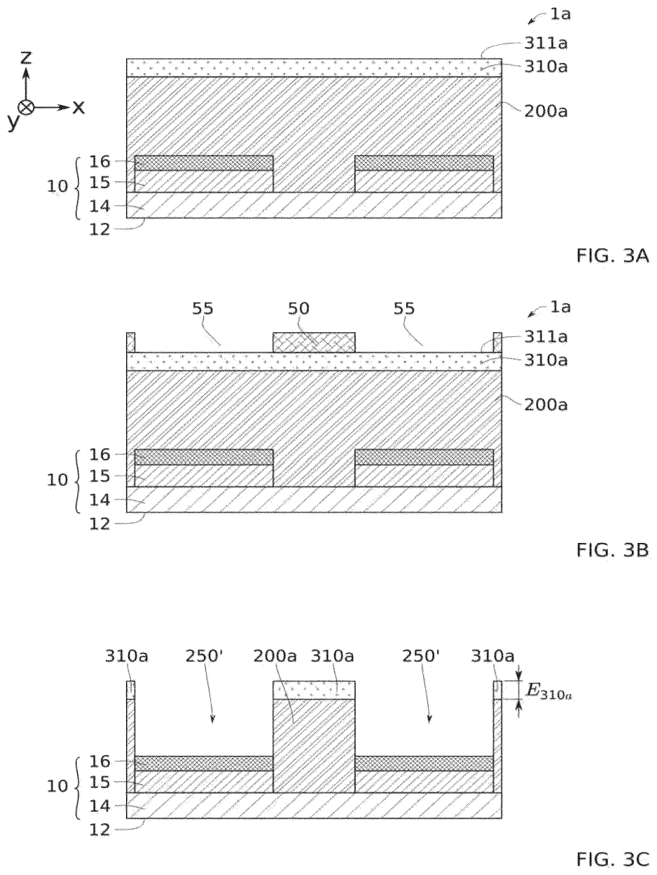

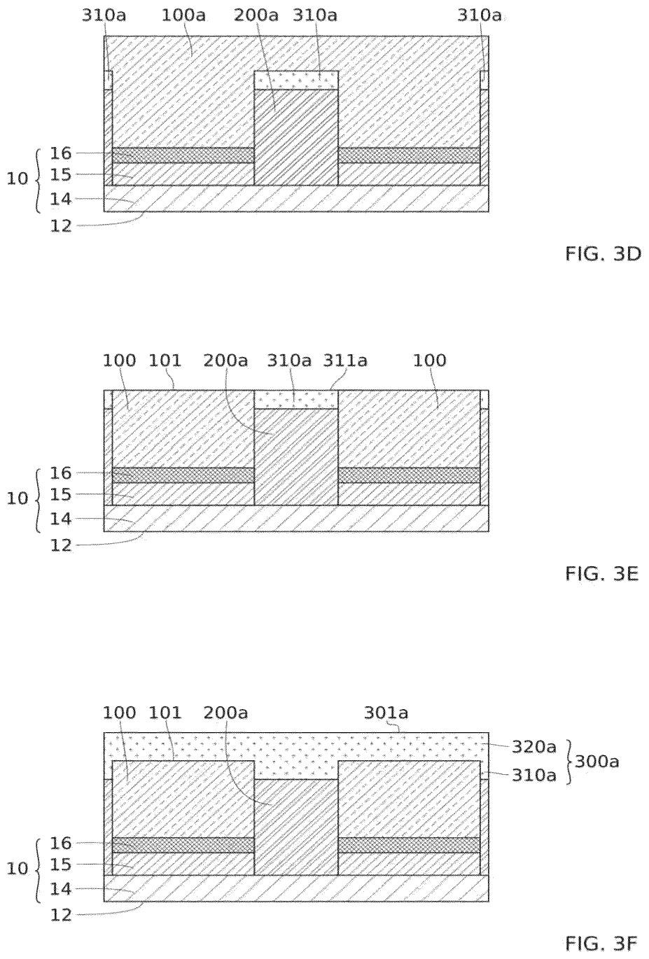

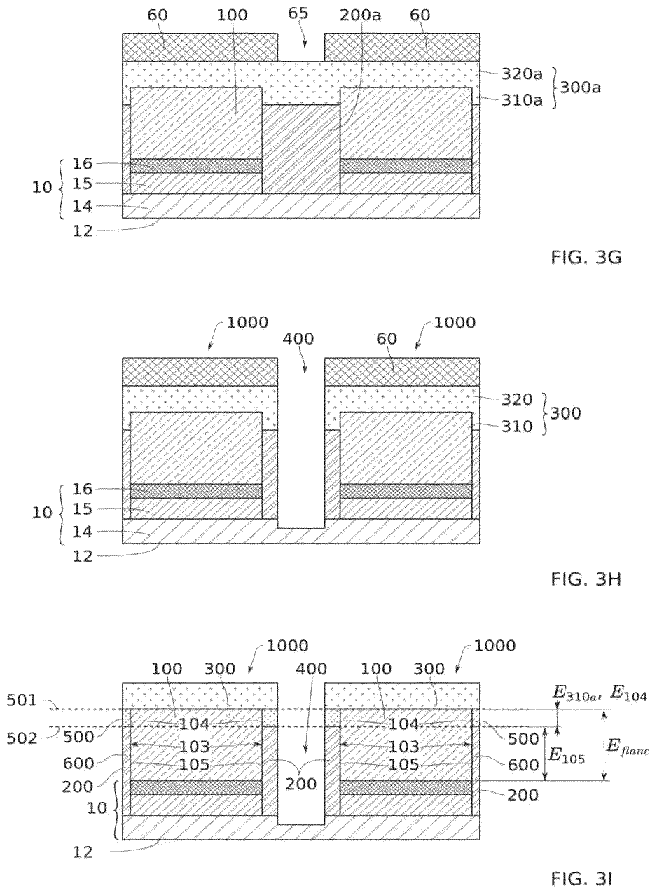

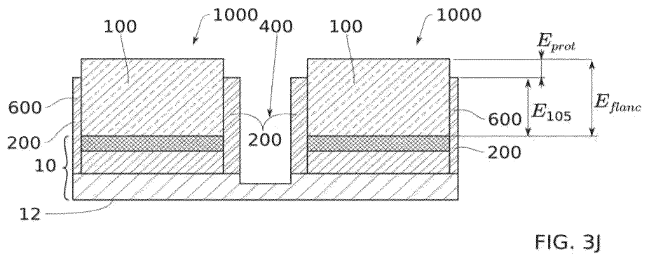

A second embodiment of the method according to the invention will now be described in reference to FIGS. 3A to 3J.

A first step consists of the provision of a stack comprising the substrate 10, a first primary layer 200a surmounting the substrate 10 and a first primary sublayer 310a surmounting the first primary layer 200a (FIG. 3A). The first primary sublayer 310a is preferably in direct contact with the first primary layer 200a.

A first etching mask 50 having openings 55 is then deposited on the upper face 311a of the first primary sublayer 310a (FIG. 3B). The parts of the first primary sublayer 310a and of the first primary layer 200a located to the right of the openings 55 are removed (FIG. 3C), then, preferably, the etching mask 50 is removed. This removal makes it possible to form secondary cavities 250′. The secondary cavities 250′ preferably extend up to the upper face 11 of the substrate 10.

Following the formation of the secondary cavities 250′ in the first primary layer 200a and in the first primary sublayer 310a, the latter are filled with the third material. As illustrated in FIGS. 3F and 3G, it is, for example, possible to form a third primary layer 100a extending into the secondary cavities 250′, in vertical alignment with the secondary cavities 250′ along the third direction Z and on the first primary sublayer 310a (FIG. 3D). The deposition of the third primary layer 100a is, preferably conform. The third primary layer 100a can then be tapered, for example, by CMP, such that it is again located with the first primary sublayer 310a (FIG. 3E).

A second primary sublayer 320a is then formed on, and preferably in direct contact with, the upper face 311A of the first primary sublayer 310a and on, and preferably in direct contact with, the top 101 of the pads 100 (FIG. 3F). The assembly constituted of the first primary sublayer 310a and of the second primary sublayer 320a is called second primary layer 300a. Trenches 400 are then formed in the second primary layer 300a and the first primary layer 200a. The trenches 400 pass through the second primary layer 300a over its entire thickness. They preferably also pass through the first primary layer 200a over its entire thickness. The formation of the trenches 400 makes it possible to divide the first primary layer 200a into a plurality of first layers 200 and the second primary layer 300a into a plurality of second layers 300. More precisely, the first primary sublayer 310a is divided into a plurality of first sublayers 310 of the second layers 300, and the second primary sublayer 320a is divided into a plurality of second sublayers 320 of the second layers 300. Advantageously, at least some of the trenches 400 extend into the substrate 10. This can make it possible, according to the targeted applications, to single out different zones of the substrate 10, for example, to electrically insulate them from one another.

Thus, the stack 1 is obtained, comprising the substrate 10 surmounted by the structures 1000, each structure 1000 comprising a pad, a first layer 200 and a second layer 300 (FIG. 3I).

As described in the scope of the first embodiment, the trenches 400 can be formed through openings 65 of a second etching mask 60 deposited on the second primary layer 300a (FIGS. 3G and 3H). This second etching mask 60 is advantageously removed after the formation of the trenches 400.

In the scope of the second embodiment, the second layer 300-more precisely, the first sublayer 310 of the second layer 300-covers a part of the flank 103. Prior to the removal step, the first layer 200 extends over only one portion of the flank 103 of the pad 100 and does not extend up to the top 101 of the pad 100. Thus, for a structure 100, the removal portion 500 is at least formed by the first sublayer 310 of the second layer 300. According to an advantageous example illustrated in FIG. 3I, the removal portion 500 extends only into the first sublayer 310 of the second layer 300. It can, however, also be considered to remove a part of the first layer 200 to form the protrusion.

The removal portion 500 is removed selectively with respect to the pad 100 after the formation of the trenches 400.

As illustrated by the passage from FIG. 3I to FIG. 3J, the removal of the removal portion 500 advantageously comprises the removal of all of the second layer 300, always selectively with respect to the pad 100.

In this second embodiment, the pads 100 project with respect to the first primary layer 200 as soon as they are formed. This comes from the fact that the pads 100 are formed in the secondary cavities 250′, delimited, in any plane parallel to the transverse plane XY, on the one hand, by the first primary layer 200a and, on the other hand, by the first primary sublayer 310a. The height Eₚᵣₒₜ of the protrusion obtained after removal of the removal portion 500 is therefore typically defined by the thickness E₃₁₀ₐ, measured along the third direction Z of the first primary sublayer 310a. In particular, if, for a structure 1000, the removal layer 500 corresponds to the first sublayer 310 of the third layer 300, substantially, Eₚᵣₒₜ=E₃₁₀ₐ.

An advantage of the second embodiment is the excellent control of the height Eₚᵣₒₜ of the protrusion. As mentioned above, this height can be defined from the deposition of the first primary sublayer 310a, yet the thickness of a layer during its deposition is a parameter, very well understood in the industry. Therefore, E₃₁₀ₐ and therefore Eₚᵣₒₜ can be accurately controlled.

This embodiment can also make it possible to form a protrusion having a particularly significant height Eₚᵣₒₜ. The removal of the second material forming the removal portion 500 selectively with regards to the third material forming the pad 100 can indeed be performed without difficulty over a significant height, typically from 50 to 200 nm.

All the steps described in the scope of this second embodiment can be implemented in other embodiments of the method according to the invention. The advantages that these steps have are also transposable to other embodiments. It is, in particular, possible to use the principle of a deposition of the second layer 300 secondly (first sublayer 310 and second sublayer 320) and of the formation of the pad 100 between the formation of the first primary sublayer 310a and the formation of the second primary sublayer 320a during other variants of the method according to the invention.

Third example of an implementation of the method according to the invention

A third example of an embodiment of the method according to the invention will now be described in reference to FIGS. 4A to 4H.

The steps making it possible to obtain the substrate 10 surmounted by the first primary layer 200a comprising cavities 250 (FIG. 4A) can be similar to those described for the first embodiment in reference to FIGS. 2A to 2C.

A third primary layer 100a is then formed in the cavities 250 and on the upper face 201a of the second primary layer 200a. The third primary layer 100a is preferably conform. Its upper face 101a preferably extends into a plane parallel to the transverse plane XY.

After the formation of the third primary layer 100a, a removal of the portions of the third primary layer 100a surmounting the first primary layer 200a is performed. This makes it possible to update the upper face 201a of the first primary layer 200a. This removal also makes it possible to single out the third primary layer 100a into pads 100.

This removal can be performed by tapering, for example, by CMP, of the first primary layer 200a of the third primary layer 100a. A CMP method can indeed make it possible to taper the first primary layer 200a selectively with regards to the third primary layer 100a, by means of a wise choice of CMP slurry and of the CMP pad.

According to another example, this removal is performed, for example by wet etching, through a mask having openings overhanging the first primary layer 200a (not represented in the figures).

As illustrated in FIG. 4D, a second primary layer 300a is then formed on the pads 100 and the first primary layer 200A. The second primary layer 300a is preferably in contact with the top 101 of the pads 100 and of the upper face 201A of the first primary layer 200A.

Trenches 400 are then formed in the second primary layer 300a and the first primary layer 200a (FIG. 4G). The trenches 400 pass through the second primary layer 300a over its entire thickness. They preferably also pass through the first primary layer 200a over its entire thickness.

The formation of the trenches 400 makes it possible to divide the first primary layer 200a into a plurality of first layers 200 and the second primary layer 300a into a plurality of second layers 300. More precisely, the first primary sublayer 310a is divided into a plurality of first sublayers 310 of the second layers 300, and the second primary sublayer 320a is divided into a plurality of second sublayers 320 of the second layers 300.

Thus, the stack 1 is obtained, comprising the substrate 10 surmounted by the structures 1000, each structure 1000 comprising a pad, a first layer 200 and a second layer 300 (FIG. 4G).

As described in the scope of the first embodiment, the trenches 400 can be formed through openings 65 of a second etching mask 60 deposited on the second primary layer 300a (FIGS. 4E and 4F). This second etching mask 60 is advantageously removed after the formation of the trenches 400.

In the scope of the third embodiment, the second layer 300 covers a part of the flank 103. Prior to the removal step, the first layer 200 extends over only one portion of the flank 103 of the pad 100 and does not extend up to the top 101 of the pad 100.

Thus, for a structure 100, the removal portion 500 is at least formed by a part of the second layer 300. According to an advantageous example illustrated in FIG. 4G, the removal portion 500 extends only into the second layer 300. It can, however, also be considered to remove a part of the first layer 200 to form the protrusion.

The removal portion 500 is removed selectively with respect to the pad 100 after the formation of the trenches 400.

As illustrated by the passage from FIG. 4G to FIG. 4H, the removal of the removal portion 500 advantageously comprises the removal of all of the second layer 300, always selectively with respect to the pad 100.

This embodiment can also make it possible to form a protrusion having a particularly significant height Eₚᵣₒₜ, potentially even greater than by implementing the second embodiment described above. The removal of the second material forming the removal portion 500 selectively with regards to the third material forming the pad 100 can indeed be performed without difficulty over a significant height, typically 50 to 200 nm.

All the steps described in the scope of this second embodiment can be implemented in other embodiments of the method according to the invention. The advantages that these steps have are also transposable to other embodiments. It is, in particular, possible to use the principle of a tapering by CMP to form pads 100 projecting with respect to the third primary layer 100a, then a protection of the top 101 of the pads 100 during other variants of the method according to the invention.

In all the embodiments described above, during the formation of the trenches 400, the top 101 of the pads 100 is covered by the second primary layer 300a. This has the advantage of protecting this top 101 and, in particular, of making it possible to preserve its surface roughness level, which could be highly impacted during the formation of the trenches 400. The surface roughness obtained after tapering the second primary layer 300a or the pads 100, according to the embodiment, can be controlled by adjusting certain tapering parameters. In particular, the CMP suspension, sometimes called CMP slurry, used during the tapering step can be chosen according to the surface roughness targeted for the pads 100. This choice can, quite specifically, be made according to the characteristic, often nanometric dimension, of the abrasive particles contained in the CMP suspension. The CMP suspension is advantageously chosen, such that the surface roughness of the pads 100 is com-patible with their bonding with a determined object, according to the targeted applications. This can, for example, be a thin film with the basis of the third material.

The roughness R₁₀₁ of the top 101 of the pads 100 is advantageously less than 2 nm, preferably less than 1.5 nm.

Moreover, another feature common to the embodiments described, is the fact that the step of tapering the third primary layer 100A making it possible to obtain the pads 1 (passage from FIG. 2D to FIG. 2E in the first embodiment, from FIG. 3D to FIG. 3E in the second embodiment and from FIG. 4B to 4C in the third embodiment) occurs before the step of forming the trenches 400. This makes it possible to avoid, during a CMP step subsequent to a step of singling out the structures 1000 (i.e. a step of forming the trenches 400), CMP suspension residues remaining in the trenches 400. These residues are indeed very difficult to remove and constitute a pollution thereafter in the method. They could, in particular, damage the correct adhesion of the pads 100 with a surface onto which they would be sought to be bonded.

The removals of material mentioned above (formation of the cavities 250, formation of the trenches 400, removal of the removal portion 500, removal of the second layer 300, etc.) can be performed by wet etching. The removal of the different etching masks 50, 60 can be done by stripping.

Through the different embodiments described above, it clearly appears that the invention proposes a method for preparing a stack in view of an assembly with another stack or substrate, simple to implement. It makes it possible to put, at each structure 1000, a portion of the pad 100 protruding with respect to the first layer. These protrusions can be used for bonding or for transferring the stack onto another stack or substrate. In particular, as mentioned above, the top 101 of the pads 100 is protected during the method and preserves a roughness suitable for a direct bonding.

Through the different embodiments described above, it clearly appears that the invention proposes a stack and a method for manufacturing this stack, enabling an effective transfer of structures from one stack to another. The presence of protrusions according to the invention indeed enables an effective bonding, of one or more pads or structures to a receiving stack, not requiring a dimensional control greater than the control commonly accessible in the industry, and not requiring any heating step, risking causing high distortions and/or high mechanical stresses within the stacks.

The invention is not limited to the embodiments described above and extends to all the embodiments covered by the invention.

1. A method for preparing a stack comprising
providing a stack comprising a substrate surmounted by a plurality of structures separated by trenches, each structure comprising:
a pad comprising a top and at least one flank,
a first layer based upon a first material and surmounting the substrate, the first layer covering at least one part of the at least one flank of the pad,
a second layer based upon a second material and covering at least the top of the pad,
a removal portion, covering an upper part of the flank of the pad, the upper part of the flank extending from the top of the pad, the removal portion being formed by at least one from among the first layer and the second layer, and
a covering portion, covering a lower part of the flank of the pad and extending from the removal portion, the covering portion being formed by the first layer,
removing the second layer, and
removing the removal portion while leaving the covering portion in place, so as to expose the upper part of the flank of the pad the upper part of the flank of the pad forming a protrusion beyond the covering portion.

2. The method according to claim 1, wherein the substrate has a lower face extending mainly along a transverse plane defined by a first direction and a second direction, the protrusion having a height Eₚᵣₒₜ along a third direction perpendicular to the transverse plane, such that Eₚᵣₒₜ≤0.5*E_{flank}, E_{flank} being a height of the flank of the pad taken along the third direction.

3. The method according to claim 1, wherein Eₚᵣₒₜ≥5 nm.

4. The method according to claim 1, wherein removing the second layer and removing the removal portion are performed during one single etching step.

5. The method according to claim 1, wherein the removal portion is formed only by the first layer.

6. The method according to claim 5, wherein, prior to removing the removal portion, the first layer extends up to the top of the pad.

7. The method according to claim 5, wherein removing the removal portion is performed by time control.

8. The method according to claim 1, wherein the removal portion is formed in part at least by the second layer.

9. The method according to claim 8, wherein the removal portion is formed only by the second layer.

10. The method according to claim 8, wherein removing the removal portion comprises etching the second layer selectively with regard to the first layer.

11. The method according to claim 8, wherein providing the stack comprises:
forming the first layer,
forming the pad, and
forming the second layer,
wherein forming the second layer comprises:
after forming a first primary layer configured to form the first layer and prior to forming the pad, forming a first primary sublayer of a second primary layer configured to form the second layer, the first primary sublayer surmounting the first primary layer, the first primary sublayer being shaped, such that after forming the trenches separating the structures, the first primary sublayer forms a first sublayer of the second layer covering a part of the flank of the pad and forming the removal portion, and
after forming the pad forming a second primary sublayer of the second primary layer, the second primary sublayer covering the first primary sublayer, the second primary sublayer being shaped, such that after forming the trenches separating the structures, the second primary sublayer forms a second sublayer of the second layer surmounting at least the pad.

12. The method according to claim 8, wherein providing the stack comprises:
forming the first layer
forming the pad and
forming the second layer
wherein a second primary layer, shaped so as to form the second layer after forming the trenches separating the structures, is deposited:
on the pad and
on a first primary layer shaped so as to form the first layer after forming the trenches, after forming the pad.

13. The method according to claim 1, wherein the pads are formed of a third material, the third material being based upon one from among copper, aluminium, tungsten and titanium.

14. The method according to claim 1, wherein the first material is based upon one from among: SiO₂, SiN and Si.

15. The method according to claim 1, wherein the second material is based upon one from among: SiN, SiO₂ and Si.

16. A stack comprising a substrate surmounted by a plurality of structures separated by trenches, each structure comprising:
a pad comprising a top and at least one flank, and
a covering portion formed by a first layer based upon a first material and surmounting the substrate covering a lower part, of the at least one flank of the pad and exposing an upper part of the at least one flank of the pad, an upper part of the pad forming a protrusion with respect to the first layer.

17. The stack according to claim 16, wherein the protrusion has a height Eₚᵣₒₜ greater than 5 nm. the height Eₚᵣₒₜ being taken along a third direction perpendicular to a transverse plane Y) into which a lower face of the substrate mainly extends.

18. A method for bonding or transferring at least one pad comprised in the stack according to claim 16 on a receiving stack:
providing the stack
providing the receiving stack having an upper face and
performing a direct bonding of the top of the at least one pad of the stack on the upper face of the receiving stack.
